(19) United States
(12) Patent Application Publication
(10) Pub. No.: US 2007/0218685 A1
(43) Pub. Date: Sep. 20, 2007

(54) Method of forming trench contacts for MOS transistors

(76) Inventors: Swaminathan Sivakumar, Portland, OR (US); Charles Wallace, Portland, OR (US); Alison V. Davis, Hillsboro, OR (US); Nadia M. Rahhal-Orabi, Hillsboro, OR (US)

Correspondence Address: INTEL CORPORATION;c/o INTELLEVATE, LLC, P.O. BOX 52050, MINNEAPOLIS, MN, 55402, US

(21) Appl. No.: 11/384,143

(22) Filed: Mar. 17, 2006

(51) Int. Cl. H01L 21/44

(52) U.S. Cl. 438/675; 257/E21.585

(57) ABSTRACT

A method to form transistor contacts begins with providing a transistor that includes a gate stack and first and second diffusion regions formed on a substrate, and a dielectric layer formed atop the gate stack and the diffusion regions. A first photolithography process forms first and second diffusion trench openings for the first and second diffusion regions. A sacrificial layer is then deposited into the first and second diffusion trench openings. Next, a second photolithography process forms a gate stack trench opening for the gate stack and a local interconnect trench opening coupling the gate stack trench opening to the first diffusion trench opening. The second photolithography process is carried out independent of the first photolithography process. The sacrificial layer is then removed and a metallization process is carried out to fill the first and second diffusion trench openings, the gate stack trench opening, and the local interconnect trench opening with a metal layer.

### BACKGROUND

Metal-oxide-semiconductor (MOS) transistors, such as MOS field effect transistors (MOSFET), are commonly used in the manufacture of integrated circuits. FIG. 1A illustrates a conventional MOS transistor 100 that includes a gate stack 102 formed atop a semiconductor substrate 104. The gate stack 102 generally consists of a conductive metal or polysilicon layer formed on an insulating oxide layer. The gate stack 102 is flanked by two diffusion regions 106, also known as a source region and a drain region. The diffusion regions 106 are regions within the semiconductor substrate 104 that have been implanted with dopants such as boron, aluminum, phosphorous, arsenic, or antimony. Between the source and drain regions, directly subjacent to the gate stack 102, is a channel region 108.

Typically, three electrical contacts 110 are made to the MOS transistor 100. Two contacts 110 are made to the two diffusion regions 106 (i.e., one to the source region and one to the drain region) and one contact 110 is made to the gate stack 102. As shown in the cross-sectional view of FIG. 1B, the three contacts 110 are cylindrical. For transistors used in nodes that are 90 nanometer (nm) or greater, the use of cylindrical contacts has been acceptable. Unfortunately, as nodes are scaled down to the 45 nm level and beyond, the transistors and contacts become increasingly smaller and the electrical resistance inherent in cylindrical contacts increases to unacceptable levels.

Accordingly, improved electrical contacts are needed for small scale MOS transistors, such as transistors used in 45 nm nodes, as well as methods for manufacturing such improved electrical contacts.

### BRIEF DESCRIPTION OF THE DRAWINGS

FIGS. 1A and 1B illustrate conventional cylindrical contacts for a MOS transistor.

FIG. 2 is a method of forming electrical contacts to a MOS transistor in accordance with an implementation of the invention.

FIGS. 3A to 3J illustrate structures that are formed while carrying out the method of FIG. 2.

FIG. 4 is a method of forming electrical contacts to a MOS transistor in accordance with an alternate implementation of the invention.

FIGS. 5A to 5F illustrate structures that are formed while carrying out the method of FIG. 4.

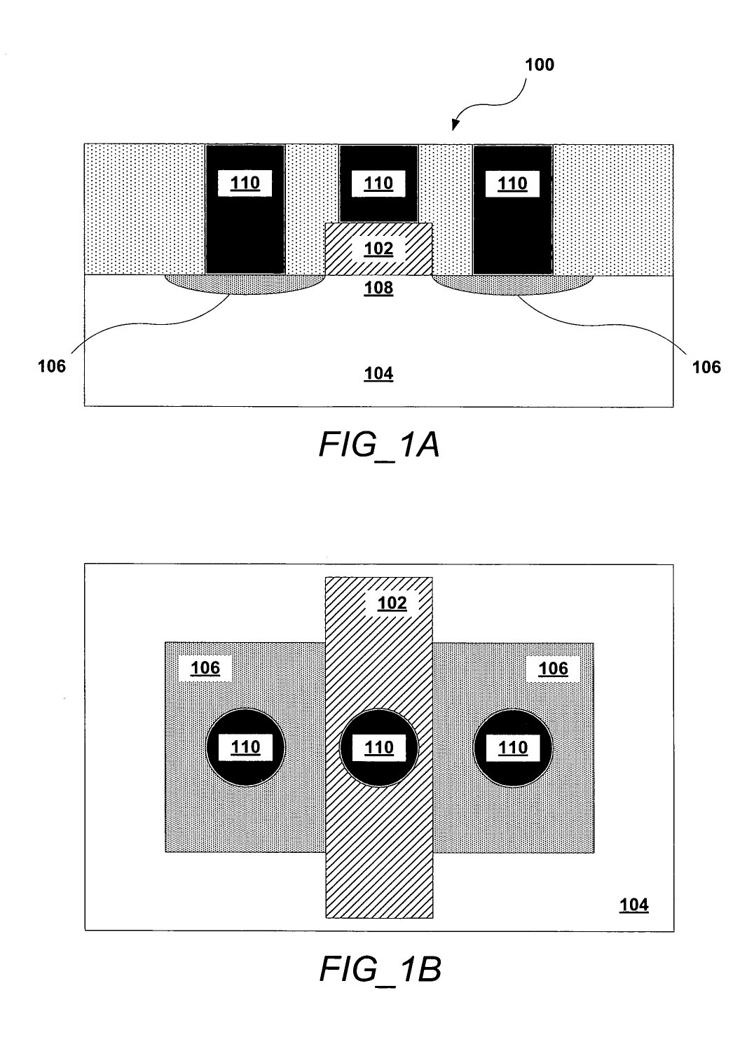

### DETAILED DESCRIPTION

Described herein are systems and methods of forming MOS transistors having trench contacts and localized interconnects. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

Implementations of the invention provide trench-shaped electrical contacts for MOS transistors, as well as methods of forming such trench contacts. The trench contacts include electrical connections to the diffusion regions (e.g., a source region and a drain region) and the gate stack of a MOS transistor. Trench contacts maximize the surface area in contact with the diffusion regions and the gate stack and therefore reduce electrical resistance relative to conventional round contacts. In some implementations, the structures and methods provide localized interconnects, for example, a local interconnect between a gate stack and an adjacent diffusion region of a MOS transistor.

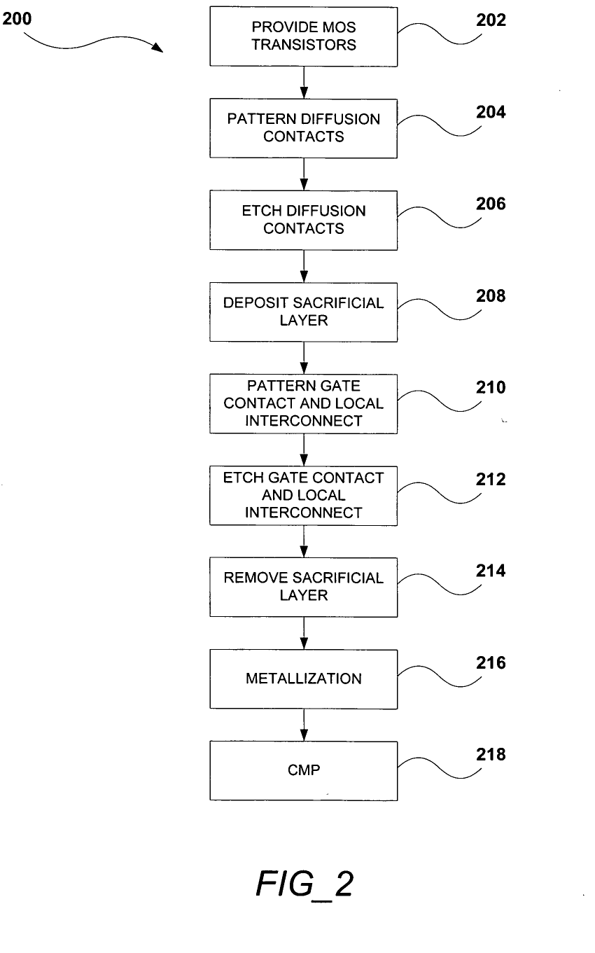

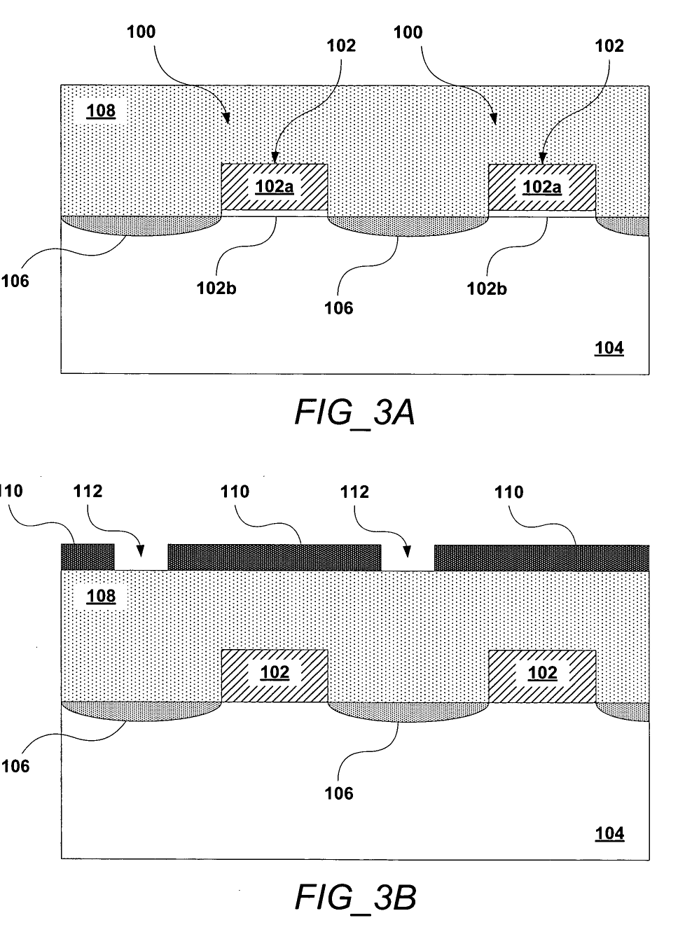

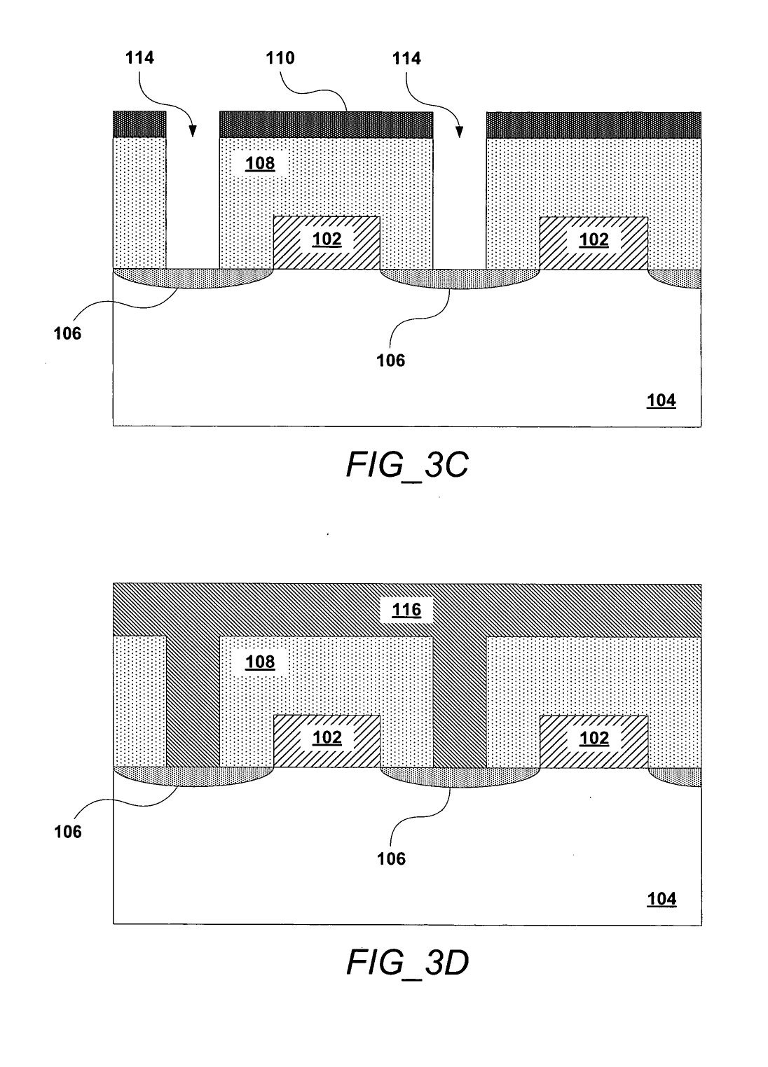

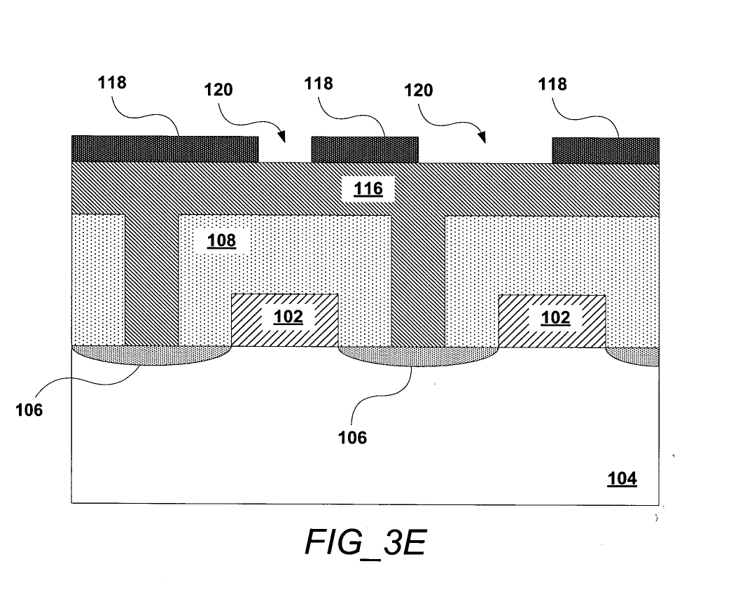

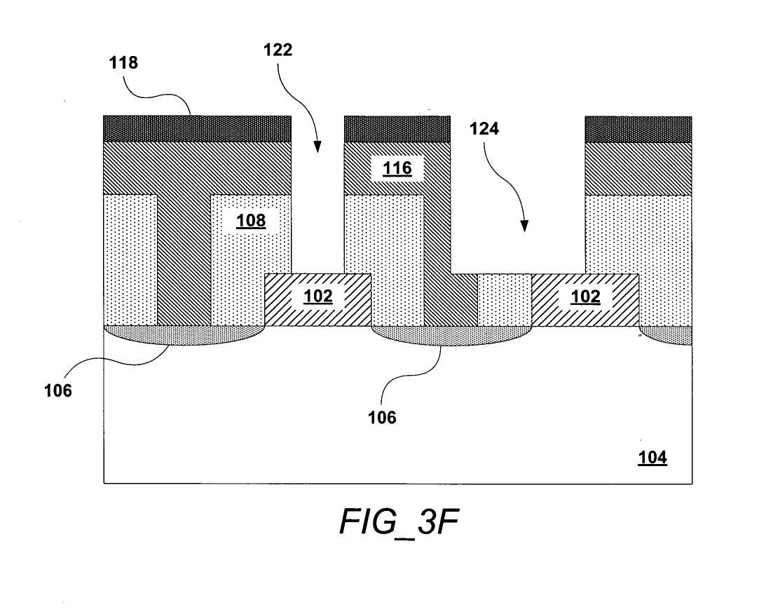

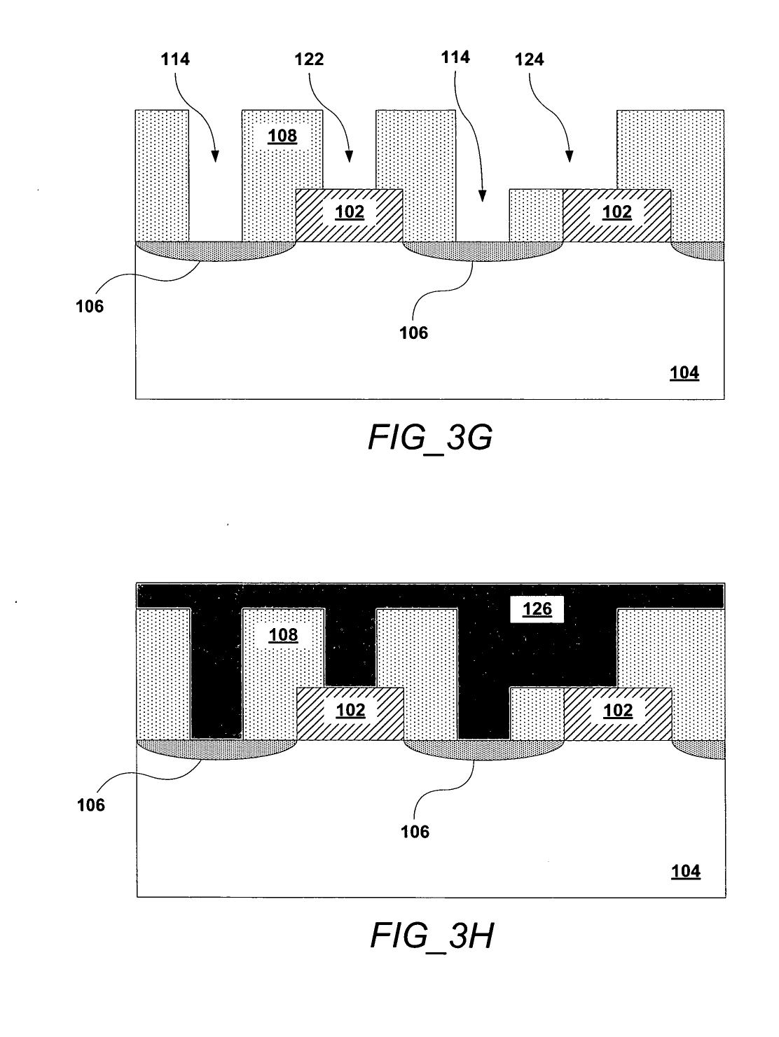

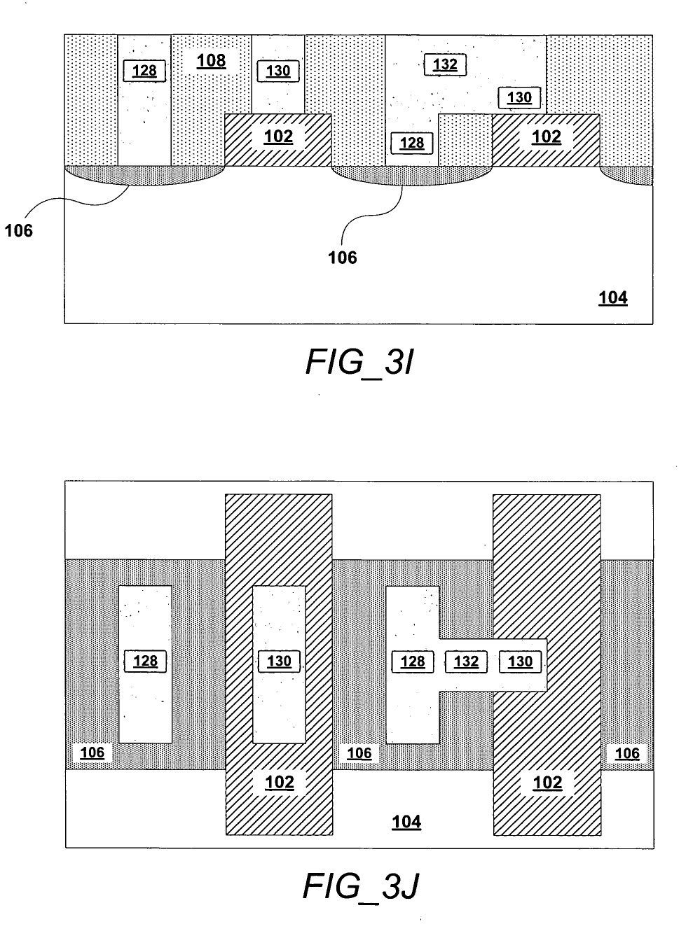

FIG. 2 is a method 200 of forming trench contacts for a MOS transistor in accordance with an implementation of the invention. The method 200 includes processes for forming a local interconnect between a gate stack and an adjacent diffusion region. FIGS. 3A to 3J illustrate various structures that are formed while carrying out the processes of the method 200. For clarity, the method 200 of FIG. 2 will be described in association with the structures shown in FIGS. 3A to 3J.

First, a MOS transistor is provided (process 202 of FIG. 2). Turning to FIG. 3A, a pair of MOS transistors 100 are illustrated that are formed on a semiconductor substrate 104. The substrate 104 may be formed using a bulk silicon or a silicon-on-insulator substructure. In other implementations, the substrate 104 may be formed using alternate materials, which may or may not be combined with silicon, that include but are not limited to germanium, indium antimonide, lead telluride, indium arsenide, indium phosphide, gallium arsenide, or gallium antimonide. Although a few examples of materials from which the substrate 104 may be formed are described here, any material that may serve as a foundation upon which a semiconductor device may be built falls within the spirit and scope of the present invention.

Each MOS transistor 100 includes a gate stack 102 consisting of a gate electrode 102a and a gate oxide layer 102b. The gate electrode 102a is a conductive layer that may be formed from one or more metal layers. Metal layers that may be used in the gate electrode 102a include, but are not limited to, copper, aluminum, hafnium, zirconium, titanium, tantalum, titanium carbide, zirconium carbide, tantalum carbide, hafnium carbide, aluminum carbide, other metal carbides, ruthenium, palladium, platinum, cobalt, nickel, ruthenium oxide, other conductive metal oxides, titanium nitride, tungsten, tantalum nitride, cobalt, or an alloy of two or more of these metals. When the gate electrode 102a is a metal, the corresponding gate oxide layer 102b may consist of a thin, high-k dielectric layer. High-k dielectric materials that may be used for the gate oxide layer 102b include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In alternate implementations, the gate electrode 102a may consist of a polysilicon layer and its corresponding gate oxide layer 102b may consist of a silicon dioxide layer.

For clarity, FIGS. 3B through 3I simply illustrate the gate stack 102 and do not illustrate the individual gate electrode 102a and gate oxide layer 102b. Those of ordinary skill in the art, however, will understand that the gate stack 102 includes the gate electrode 102a and the gate oxide layer 102b.

As shown, the gate stack 102 of each MOS transistor 100 is flanked by at least two diffusion regions 106. The diffusion regions 106 form source and drain regions for each MOS transistor 100. The diffusion regions 106 are formed by implanting dopants into regions of the semiconductor substrate 104 that are adjacent to the gate stacks 102. As described above, these dopants may include, but are not limited to, boron, aluminum, phosphorous, arsenic, and antimony.

A dielectric layer 108 may be formed atop the MOS transistors 100, as shown in FIG. 3A. The dielectric layer 108 may be formed from materials such as silicon dioxide or carbon doped oxide. In some implementations, the dielectric layer 108 may be formed from materials such as silicon nitride, organic polymers such as perfluorocyclobutane and polytetrafluoroethylene, organosilicate glass, fluorosilicate glass (FSG), organosilicates such as silsesquioxane, and siloxane.

After the MOS transistor is provided, a first photolithography process may be carried out to form trench openings that are in contact with the diffusion regions. Such trench openings, referred to herein as diffusion trench openings, may later be filled with metal to form electrical contacts to the diffusion regions.

To form the diffusion trench openings, the first photolithography process includes depositing a photoresist material on the dielectric layer 108 and patterning the photoresist using known photolithography techniques to define the diffusion trench openings (204 of FIG. 2). For example, a photoresist material may be deposited using a spin-on deposition (SOD) process, exposed to radiation (e.g., optical, electron beam, or extreme ultraviolet) through a mask that transfers a pattern for the trench openings, and exposed to a developer solution. The photoresist material remaining after development, shown in FIG. 3B as photoresist 110, masks selected portions of the dielectric layer 108 such that any exposed portions 112 will define the trench openings.

Next, the first photolithography process includes etching the exposed dielectric material to form diffusion trench openings (206 of FIG. 2). The etching process may be carried out using an etch chemistry that is appropriate for the dielectric material used. For instance, if the dielectric layer is silicon dioxide or carbon doped oxide, a CXFYH, etch chemistry may be used. The trench openings that are formed may be cleaned using conventional processes, for instance, a plasma clean, a wet chemical clean, or a combination of both. FIG. 3C illustrates the diffusion trench openings 114. As shown, the diffusion trench openings 114 are in contact with the diffusion regions 106.

Unlike conventional prior art processes, a contact opening for the gate stack 102 is not patterned and etched simultaneously with the diffusion trench openings. In accordance with the invention, the process flow of method 200 segregates processes for forming the diffusion trench openings 114 from processes for forming contact openings for the gate stacks 102. Because the materials used in the diffusion regions 106 may have different compatibility requirements than the materials used for the gate stack 102, segregating these processes in accordance with the invention allows the diffusion trench openings 114 to be optimized without adversely affecting contact openings formed for the gate stacks 102. For instance, since a contact opening for the gate stack 102 is not being etched, the gate stack 102 will not be exposed at this process stage. This means that the etch does not have to have selectivity to the material used for the gate stack 102. The etch can therefore be optimized to simply have high selectivity to the materials used in the diffusion regions 106. Furthermore, clean chemistries that would otherwise damage the material used for the gate stack 102 may now be used.

Next, a sacrificial layer is deposited into the diffusion trench openings and onto the dielectric layer (208 of FIG. 2). The sacrificial layer may be planarized if needed, for instance, using a chemical mechanical polishing (CMP) process. FIG. 3D illustrates a planarized sacrificial layer 116 that has been deposited in the diffusion trench openings 114 and on the dielectric layer 108. The sacrificial layer 116 may be formed from materials that include, but are not limited to, spin-on glass, other siloxane-based materials, and organic antireflective coatings. Deposition processes such as SOD, chemical vapor deposition (CVD), physical vapor deposition (PVD), or atomic layer deposition (ALD) may be used to deposit the sacrificial layer 116. The sacrificial layer 116 provides a planar surface upon which a subsequent photolithography process may be carried out. In addition, the sacrificial layer 116 may be tailored to provide reflectivity control to enable good patterning quality at the subsequent photolithography process.

A second photolithography process may now be carried out to create trench openings that are in contact with each gate stack. Such trench openings, referred to herein as gate stack trench openings, may later be filled with metal to form electrical contacts to the gate stacks. In accordance with implementations of the invention, trench openings for one or more local interconnects may also be formed at this process stage.

To form the gate stack trench openings and local interconnect trench openings, the second photolithography process includes depositing a photoresist material on the sacrificial layer and patterning the photoresist using known photolithography techniques to define a trench opening for each gate stack as well as a trench opening for each of the one or more local interconnects (210 of FIG. 2). The photoresist material remaining after patterning, shown in FIG. 3E as photoresist 118, masks selected portions of the sacrificial layer 116 such that exposed portions 120 define the trench openings.

The second photolithography process also includes etching the sacrificial layer and portions of the underlying dielectric layer to form the gate stack trench openings and the local interconnect trench openings (212 of FIG. 2). The etching process may be carried out in a similar manner as described above. As shown in FIG. 3F, the dielectric layer 108 and the sacrificial layer 116 are etched down to the depth of the gate stack 102.

In accordance with implementations of the invention, the etch chemistry and etch parameters are optimized to ensure that the sacrificial layer 116 and the dielectric layer 108 are etched at substantially the same rate. This allows proper definition of trench openings 122 for the gate stacks 102 and at least one trench opening 124 for a local interconnect. For instance, the etch chemistry as well as the chemical composition and the deposition parameters of the sacrificial layer 116 may be tweaked to ensure that the etch rates of the sacrificial layer 116 and the dielectric layer 108 are roughly matched, as is well known in the art. The trench openings 122/124 that are formed may then be cleaned after the etch step.

It should be noted again that the process flow of method 200 segregates the processes for forming the gate stack trench openings and local interconnects from the processes for forming the diffusion trench openings. Therefore, the gate stack trench openings may be optimized without adversely affecting the diffusion trench openings. For instance, since contact openings for the diffusion regions 106 are not being etched, the diffusion regions 106 will not be exposed at this process stage. This means that the etch does not have to have selectivity to the material used for the diffusion regions 106. The etch can therefore be optimized to simply have high selectivity to the material used in the gate stack 102. Furthermore, clean chemistries that would otherwise damage the materials used for the diffusion regions 106 may now be used.

The sacrificial layer, as well as any remaining photoresist material, may then be removed to expose all of the trench openings that have been formed (214 of FIG. 2). Methods of removing sacrificial layers and photoresist material are well known in the art, and may include wet chemical etching processes and plasma etching processes.

FIG. 3G illustrates the trench openings that have been formed by the method 200. As shown, the trench openings include diffusion trench openings 114, gate stack trench opening 122, and local interconnect trench opening 124. It should be noted that local interconnect trench opening 124 also serves as a gate stack trench opening.

When the trench openings are exposed, a metallization process may be carried out to fill the trench openings with a suitable metal to form electrical contacts to the diffusion regions and gate stacks, as well as to form the local interconnects (216 of FIG. 2). FIG. 3H illustrates the result of a metallization process that fills the trench openings with a metal layer 126. Metallization processes such as CVD, plasma enhanced chemical vapor deposition (PECVD), PVD, sputter deposition, ALD, electroplating, electroless plating, or a combination of any of these processes, may be used to deposit one or more layers of metal in the trench openings.

Metals that may be used for the metallization include, but are not limited to, copper, ruthenium, palladium, platinum, cobalt, nickel, ruthenium oxide, tungsten, aluminum, titanium, tantalum, titanium nitride, tantalum nitride, hafnium, zirconium, a metal carbide, a conductive metal oxide, or combinations of the above.

The metal layer 126 may consist of multiple layers of metals. For instance, in one implementation, a first metal layer may consist of a seed layer, such as a copper seed layer or a noble metal catalyst layer, and a second metal layer may consist of a bulk metal layer such as copper. In further implementations, the various metal layers may provide various functionality, such as barrier layers, adhesion layers, and capping layers.

Finally, a CMP process may be utilized, if needed, to planarize the deposited metal layer (218 of FIG. 2). The CMP process completes the formation of separate and distinct diffusion region contacts and gate stack contacts. FIG. 3I illustrates the completed trench contacts after a CMP process. As shown in FIG. 3I, the method 200 of FIG. 2 has produced diffusion region trench contacts 128, gate stack trench contacts 130, and a local interconnect 132. FIG. 3J is a top view of the completed structure shown in FIG. 3I, illustrating that the contacts are indeed trench contacts. The dielectric layer 108 is not shown in FIG. 3J for clarity.

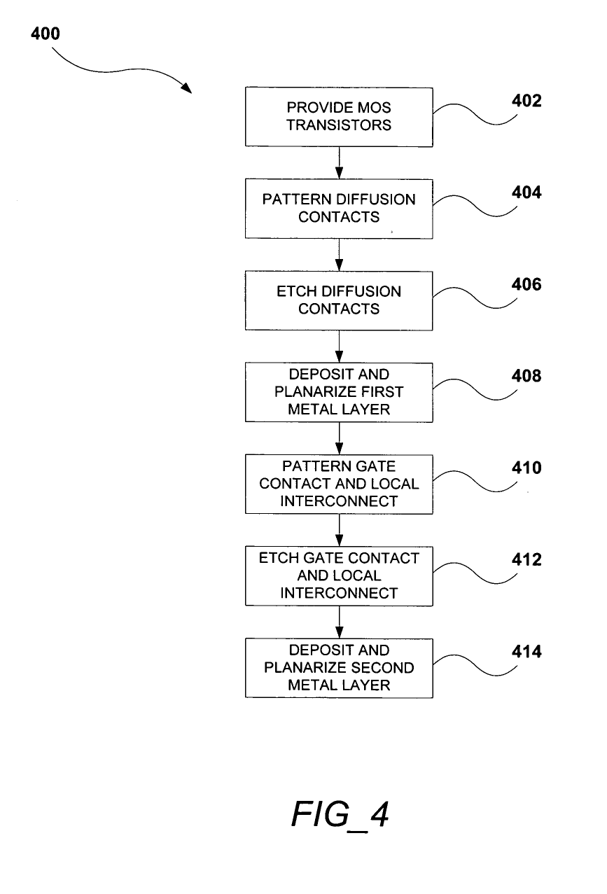

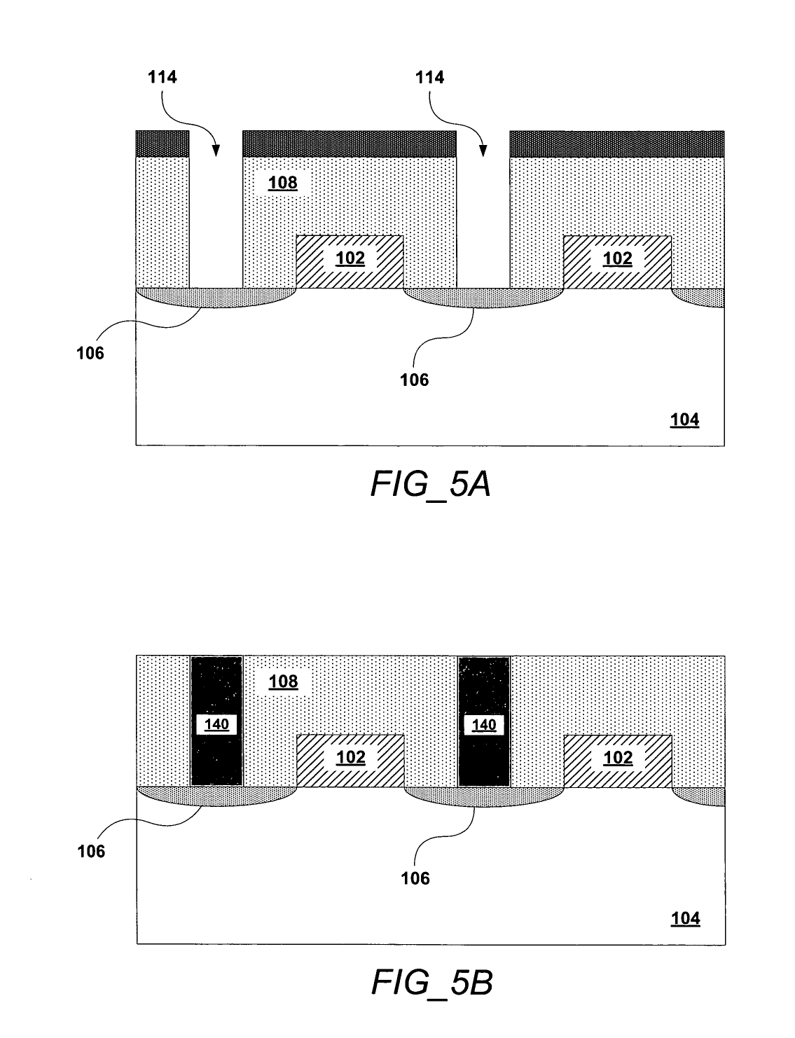

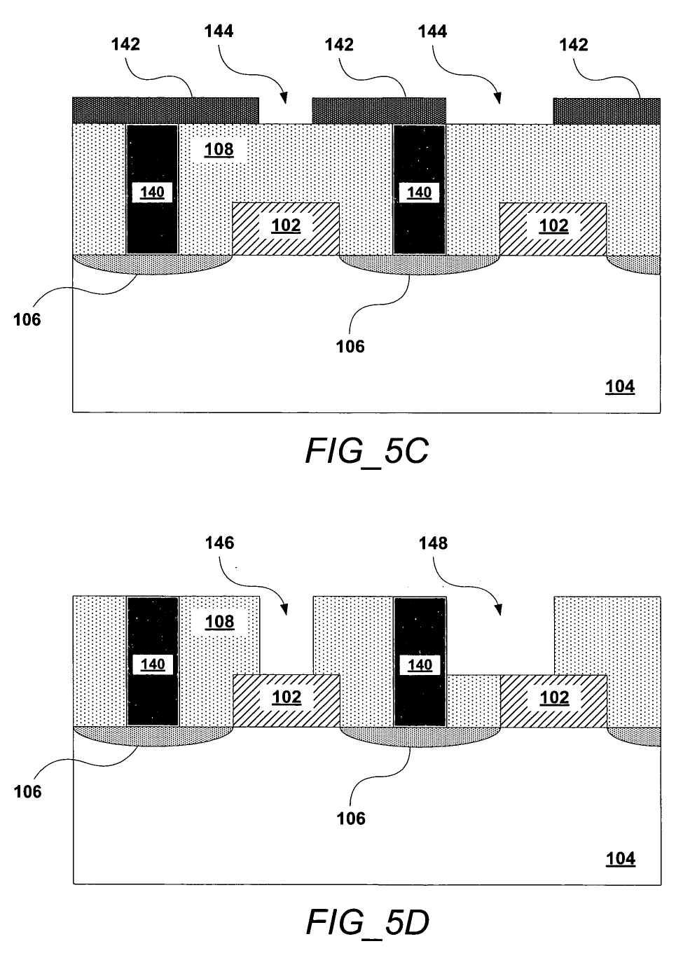

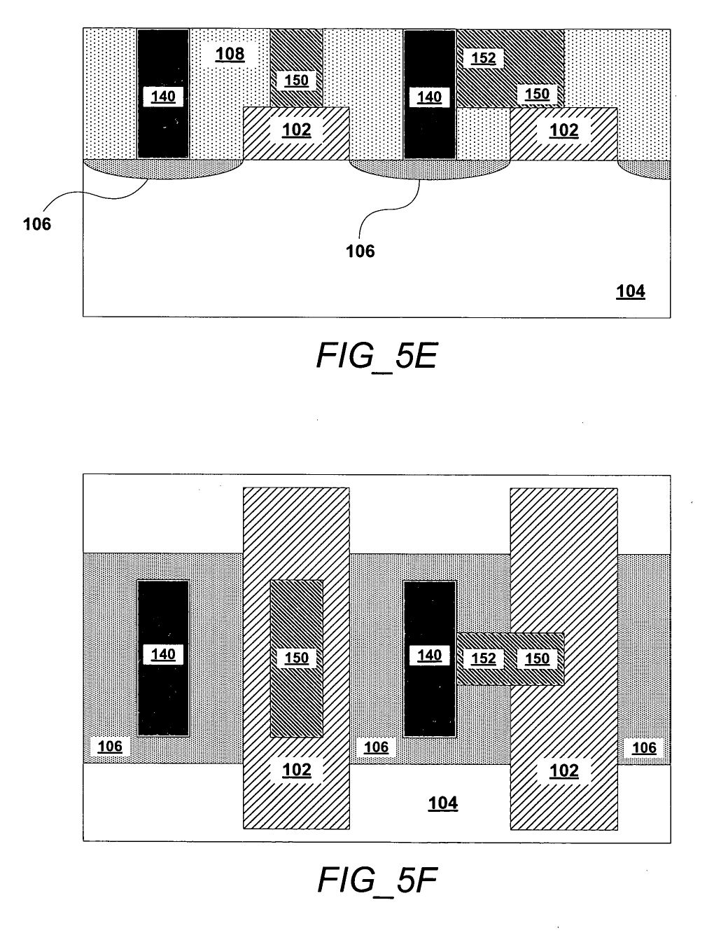

FIG. 4 is a method 400 of forming trench contacts for a MOS transistor in accordance with another implementation of the invention. FIGS. 5A to 5F illustrate various structures that are formed while carrying out the processes of the method 400. For clarity, the method 400 of FIG. 4 will be described in association with the structures shown in FIGS. 5A to 5F.

Initially, the method 400 is similar to the method 200 of FIG. 2. A MOS transistor is provided (process 402 of FIG. 4); a photoresist material is deposited on the dielectric layer 108 and patterned using known photolithography techniques to define diffusion trench openings (404 of FIG. 4); and the exposed dielectric material is etched to form the diffusion trench openings (406 of FIG. 4). FIG. 5A illustrates the diffusion trench openings 114. As shown, the diffusion trench openings 114 are in contact with the diffusion regions 106. Once again, a contact opening for the gate stack 102 is not patterned and etched at this time.

Next, a first metal layer is deposited into the diffusion trench openings and planarized (408 of FIG. 4). The metal layer may be planarized using a CMP process to remove any metal that has deposited onto the dielectric layer, thereby forming trench contacts that are in contact with the diffusion regions. FIG. 5B illustrates such a planarized metal layer that has been deposited in the diffusion trench openings to form trench contacts 140. Deposition processes such as CVD, PVD, ALD, electroless plating, or electroplating may be used to deposit the first metal layer to form the trench contacts 140. As shown in FIG. 5B, the planarized trench contacts 140 and the dielectric layer 108 provide a planar surface upon which a subsequent photolithography process may be carried out. Optionally, a sacrificial layer may be deposited to provide a planar surface.

The metal used in the trench contacts 140 may consist of metals or alloys that are conventionally used for electrical contacts to diffusion regions. For instance, in various implementations of the invention, metals and alloys that may be used to form the trench contacts 140 include, but are not limited to, copper, ruthenium, palladium, platinum, cobalt, nickel, ruthenium oxide, tungsten, aluminum, titanium, tantalum, titanium nitride, tantalum nitride, hafnium, zirconium, a metal carbide, a conductive metal oxide, or combinations of the above.

A second photolithography process may be carried out to create trench openings that are in contact with each gate stack, as well as trench openings for one or more local interconnects. Similar to above, a photoresist material may be deposited on the dielectric layer and the trench contacts and patterned using known photolithography techniques to define a trench opening for each gate stack as well as the one or more local interconnects (410 of FIG. 4). The photoresist material remaining after patterning, shown in FIG. 5C as photoresist 142, masks the trench contacts 140 and selected portions of the dielectric layer 108 such that exposed portions 144 define the trench openings and the local interconnects.

The dielectric layer is then etched to form trench openings that contact each gate stack and trench openings that define the one or more local interconnects (412 of FIG. 4). As shown in FIG. 5D, the dielectric layer 108 is etched down to the depth of the gate stack 102 to form a gate stack trench opening 146 and a local interconnect trench opening 148. The local interconnect trench opening 148 also serves as a gate stack trench opening. The trench openings 146/148 that are formed may then be cleaned after the etch step, for instance, using a plasma clean or a wet chemical clean.

Next, a second metal layer is deposited into the trench openings and planarized (414 of FIG. 4). The second metal layer may be planarized using a CMP process to remove any metal that has deposited onto the dielectric layer and the diffusion trench contacts, thereby forming trench contacts that are in contact with the gate stacks, as well as forming a local interconnect. FIG. 5E illustrates such a planarized second metal layer that has been deposited in the trench openings to form gate stack trench contacts 150 and a local interconnect 152. Deposition processes such as CVD, PVD, ALD, electroless plating, or electroplating may be used to deposit the second metal layer to form the gate stack trench contacts 150 and the local interconnect 152.

The metal used in the gate stack trench contacts 150 and the local interconnect 152 may consist of metals or alloys that are conventionally used for electrical contacts to gate stacks. For instance, in various implementations of the invention, metals and alloys that may be used to form the gate stack trench contacts 150 and the local interconnect 152 include, but are not limited to, copper, ruthenium, palladium, platinum, cobalt, nickel, ruthenium oxide, tungsten, aluminum, titanium, tantalum, titanium nitride, tantalum nitride, hafnium, zirconium, a metal carbide, a conductive metal oxide, or combinations of the above.

The metal used in the gate stack trench contacts 150 and the local interconnect 152 may consist of multiple layers of metals. As described above, the various metal layers may provide various functionality, such as barrier layers, adhesion layers, filler layers, and capping layers.

It should be noted again that the process flow of method 400 segregates the processes for forming the gate stack trench contact and local interconnects from the processes for forming the diffusion trench contacts. Therefore, the electrical contacts for each region may be optimized without adversely affecting the contacts for the other region. For instance, as illustrated by method 400, this enables the metal used in the diffusion trench contacts to be different than the metal used in the gate stack trench contacts and the local interconnect.

FIG. 5F is a top view of the completed structure shown in FIG. 3I, illustrating that the contacts are trench contacts formed of different metals. The dielectric layer 108 is not shown in FIG. 5F for clarity.

Accordingly, process flows to form trench contacts and local interconnects has been disclosed. In accordance with implementations of the invention, trench contacts may be patterned for both diffusion regions and gate stacks. Local interconnections of gates to diffusion regions may also be enabled in a very straightforward manner. Implementations of the invention allow for both the diffusion regions and the gate contacts to act as local interconnects.

Furthermore, implementations of the invention allow the formation of the diffusion trench contacts and the gate stack trench contacts to be decoupled, allowing for custom optimization of each. Implementations of the invention provide processes to form low resistance electrical contacts for tight transistor geometries with good low-resistance performance.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A method comprising:
providing a transistor on a substrate, wherein the transistor includes a gate stack and at least one diffusion region formed on the substrate and a dielectric layer formed atop the gate stack and the at least one diffusion region;
performing a first photolithography process to form a diffusion trench opening that is in contact with the at least one diffusion region;
depositing a sacrificial layer into the diffusion trench opening;
performing a second photolithography process to form a gate stack trench opening that is in contact with the gate stack, wherein the second photolithography process is carried out independent of the first photolithography process;
removing the sacrificial layer; and
performing a metallization process to fill the diffusion trench opening and the gate stack trench opening with a metal layer.

2. The method of claim 1, wherein first photolithography process comprises:
depositing a photoresist material on the dielectric layer;
patterning the photoresist material to expose a portion of the dielectric layer that defines the diffusion trench opening; and
etching the dielectric layer to form the diffusion trench opening.

3. The method of claim 2, wherein the etching of the dielectric layer comprises using an etch chemistry that has high selectivity to the at least one diffusion region.

4. The method of claim 1, wherein the sacrificial layer comprises a spin-on glass, a siloxane-based material, or an organic antireflective coating.

5. The method of claim 1, wherein the sacrificial layer is deposited using a SOD process, a CVD process, a PVD process, or an ALD process.

6. The method of claim 1, wherein the second photolithography process comprises:
depositing a photoresist material on the sacrificial layer;
patterning the photoresist material to expose a portion of the sacrificial layer and/or the dielectric layer that defines the gate stack trench opening; and
etching the sacrificial layer and the dielectric layer to form the gate stack trench opening.

7. The method of claim 1, wherein the second photolithography process further forms a local interconnect trench opening for coupling the gate stack to the diffusion region.

8. The method of claim 6, wherein the etching of the sacrificial layer and the dielectric layer comprises optimizing an etch chemistry and a set of etch parameters to ensure that the sacrificial layer and the dielectric layer are etched at substantially the same rate.

9. The method of claim 6, wherein the etching of the sacrificial layer and the dielectric layer comprises using an etch chemistry that has high selectivity to the gate stack.

10. The method of claim 1, wherein the removing of the sacrificial layer is performed using a wet chemical etching process or a plasma etching process.

11. The method of claim 1, wherein the metallization process comprises CVD, PECVD, PVD, sputter deposition, ALD, electroplating, or electroless plating.

12. The method of claim 1, wherein the metal layer comprises one or more of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

13. The method of claim 1, wherein the metal layer comprises two or more metal layers.

14. The method of claim 13, wherein a first metal layer comprises a seed layer and a second layer comprises a bulk metal layer.

15. The method of claim 1, further comprising a CMP process to planarize the metal layer.

16. A method comprising:
providing a transistor on a substrate, wherein the transistor includes a gate stack, a first diffusion region, and a second diffusion region formed on the substrate and a dielectric layer formed atop the gate stack and the first and second diffusion regions;
performing a first photolithography process to form a first diffusion trench opening that is in contact with the first diffusion region and a second diffusion trench opening that is in contact with the second diffusion region;
depositing a sacrificial layer into the first and second diffusion trench openings;
performing a second photolithography process to form a gate stack trench opening that is in contact with the gate stack and to form a local interconnect trench opening that couples the gate stack trench opening to the first diffusion trench opening, wherein the second photolithography process is carried out independent of the first photolithography process;
removing the sacrificial layer; and
performing a metallization process to fill the first diffusion trench opening, the second diffusion trench opening, the gate stack trench opening, and the local interconnect trench opening with a metal layer.

17. The method of claim 16, wherein first photolithography process comprises:
depositing a photoresist material on the dielectric layer;
patterning the photoresist material to expose portions of the dielectric layer that define the first diffusion trench opening and the second diffusion trench opening; and
etching the dielectric layer to form the first diffusion trench opening and the second diffusion trench opening.

18. The method of claim 17, wherein the etching of the dielectric layer comprises using an etch chemistry that has high selectivity to the first and second diffusion regions.

19. The method of claim 16, wherein the sacrificial layer comprises a spin-on glass, a siloxane-based material, or an organic antireflective coating.

20. The method of claim 16, wherein the sacrificial layer is deposited using a SOD process, a CVD process, a PVD process, or an ALD process.

21. The method of claim 16, wherein the second photolithography process comprises:
depositing a photoresist material on the sacrificial layer;
patterning the photoresist material to expose portions of the sacrificial layer and/or the dielectric layer that define the gate stack trench opening and the local interconnect trench opening; and
etching the sacrificial layer and the dielectric layer to form the gate stack trench opening and the local interconnect trench opening.

22. The method of claim 21, wherein the etching of the sacrificial layer and the dielectric layer comprises optimizing an etch chemistry and a set of etch parameters to ensure that the sacrificial layer and the dielectric layer are etched at substantially the same rate.

23. The method of claim 21, wherein the etching of the sacrificial layer and the dielectric layer comprises using an etch chemistry that has high selectivity to the gate stack.

24. The method of claim 16, wherein the removing of the sacrificial layer is performed using a wet chemical etching process or a plasma etching process.

25. The method of claim 16, wherein the metallization process comprises CVD, PECVD, PVD, sputter deposition, ALD, electroplating, or electroless plating.

26. The method of claim 16, wherein the metal layer comprises one or more of copper, ruthenium, palladium, platinum, cobalt, nickel, ruthenium oxide, tungsten, aluminum, titanium, tantalum, titanium nitride, tantalum nitride, hafnium, zirconium, a metal carbide, and a conductive metal oxide.

27. The method of claim 16, further comprising a CMP process to planarize the metal layer.

28. A method comprising:
providing a transistor on a substrate, wherein the transistor includes a gate stack and at least one diffusion region formed on the substrate and a dielectric layer formed atop the gate stack and the at least one diffusion region;
performing a first photolithography process to form a diffusion trench opening that is in contact with the at least one diffusion region;
depositing a first metal layer into the diffusion trench opening;
planarizing the first metal layer;
performing a second photolithography process to form a gate stack trench opening that is in contact with the gate stack, wherein the second photolithography process is carried out independent of the first photolithography process; and
depositing a second metal layer into the gate stack trench opening.

29. The method of claim 28, wherein first photolithography process comprises:
depositing a photoresist material on the dielectric layer;
patterning the photoresist material to expose a portion of the dielectric layer that defines the diffusion trench opening; and
etching the dielectric layer to form the diffusion trench opening.

30. The method of claim 29, wherein the etching of the dielectric layer comprises using an etch chemistry that has high selectivity to the at least one diffusion region.

31. The method of claim 28, wherein the second photolithography process comprises:
depositing a photoresist material on the first metal layer;
patterning the photoresist material to expose a portion of the sacrificial layer and/or the dielectric layer that defines the gate stack trench opening; and
etching the sacrificial layer and the dielectric layer to form the gate stack trench opening.

32. The method of claim 31, wherein the etching of the sacrificial layer and the dielectric layer comprises optimizing an etch chemistry and a set of etch parameters to ensure that the sacrificial layer and the dielectric layer are etched at substantially the same rate.

33. The method of claim 31, wherein the etching of the sacrificial layer and the dielectric layer comprises using an etch chemistry that has high selectivity to the gate stack.

34. The method of claim 28, wherein the second photolithography process further forms a local interconnect trench opening for coupling the gate stack to the diffusion region.

35. The method of claim 1, wherein the metal used in the first metal layer is different than the metal used in the second metal layer.
